(19) United States
(12) Patent Application Publication
(10) Pub. No.: US 2013/0319840 A1
(43) Pub. Date: Dec. 5, 2013

(54) ONE-PIECE LAMELLAR PROJECTIVE CAPACITIVE TOUCH PANEL STRUCTURE AND METHOD OF MANUFACTURING THE SAME

(71) Applicants: FU-TIEN KU, TAOYUAN COUNTY (TW); CHIA-YEN LI, TAIPEI CITY (TW); HSIANG-CHUN YU, TAOYUAN COUNTY (TW); CHING-SHIH WEN, TAOYUAN COUNTY (TW); CHIN-YEN SHIEH, TAOYUAN COUNTY (TW)

(72) Inventors: FU-TIEN KU, TAOYUAN COUNTY (TW); CHIA-YEN LI, TAIPEI CITY (TW); HSIANG-CHUN YU, TAOYUAN COUNTY (TW); CHING-SHIH WEN, TAOYUAN COUNTY (TW); CHIN-YEN SHIEH, TAOYUAN COUNTY (TW)

(73) Assignee: WAH HONG INDUSTRIAL CORP., KAOHSIUNG (TW)

(21) Appl. No.: 13/550,023

(22) Filed: Jul. 16, 2012

(30) Foreign Application Priority Data
May 30, 2012 (TW) 101119372

(51) Int. Cl. H03K 17/975; H01H 11/00

(52) U.S. Cl. 200/600; 29/622

(57) ABSTRACT

A one-piece lamellar projective capacitive touch panel structure includes a substrate unit, a conductive unit, an insulating unit and a signal transmitting unit. The substrate unit includes a transparent substrate and a surrounding opaque layer formed on the bottom surface of the transparent substrate. The conductive unit includes a transparent conductive layer formed on the bottom surface of the transparent substrate to cover the surrounding opaque layer and a surrounding electrode layer formed on the bottom surface of the transparent conductive layer, and a terminal resistance substantially between 2000Ω and 2500Ω generated by the surrounding electrode layer. The insulating unit includes an insulating layer formed on the bottom surface of the transparent conductive layer to cover the surrounding electrode layer. The signal transmitting unit includes a signal transmitting cable between the surrounding electrode layer and the insulating layer and electrically connected to the surrounding electrode layer.

### BACKGROUND OF THE INVENTION

1. Field of the Invention

The instant disclosure relates to a touch panel structure and a method of manufacturing the same, and more particularly to a one-piece lamellar projective capacitive touch panel structure and a method of manufacturing the same.

2. Description of Related Art

Touch panels can be produced in a variety of types and sizes without mouse, button or direction key and can be used as input part of a wide variety of electronic devices. With information appliance developing, the touch panels have replaced keyboard and mouse to communicate with the information appliance. The touch panels provide users a friendly interface such that operations of computers or electronic products become simple, straightforward, lively and interesting. Depending on fields of applications, touch panels are applied to portable communication and information products (for example, personal digital assistant (PDA)), financial/commercial system, medical registration system, monitoring system, information guiding system, and computer-aided teaching system, and thereby enhancing convenience of handling for users.

Generally speaking, touch panels may be operated by means of infrared, ultrasonic, piezoelectric, capacitive or resistive sensing. The capacitive touch panel has inner wires made of transparent conductive materials on a glass substrate, and transmitting signals to integrated circuits (IC) configured on an outer flexible PCB or rigid PCB via peripheral conductive wires on the glass substrate. Such structure constitutes a touch sensor, which configured to an outer printed circuit board and a top protecting cover to complete a touch panel. A uniform electric field is generated on surface of the glass substrate when touching. Coordinates of the contact point are determined by variation of capacitance due to electrostatic reaction generated between the user's finger and the electric field when a user touches the touch panel.

### SUMMARY OF THE INVENTION

One aspect of the instant disclosure relates to a one-piece lamellar projective capacitive touch panel structure and a method of manufacturing the same.

One of the embodiments of the instant disclosure provides a one-piece lamellar projective capacitive touch panel structure, comprising: a substrate unit, a conductive unit, an insulating unit and a signal transmitting unit. The substrate unit includes a transparent substrate and a surrounding opaque layer surroundingly formed on the bottom surface of the transparent substrate. The conductive unit includes a transparent conductive layer formed on the bottom surface of the transparent substrate to cover the surrounding opaque layer and a surrounding electrode layer surroundingly formed on the bottom surface of the transparent conductive layer, wherein two opposite sides of the surrounding electrode layer is measured to obtain a terminal resistance substantially between 2000Ω and 2500Ω. The insulating unit includes an insulating layer formed on the bottom surface of the transparent conductive layer to cover the surrounding electrode layer. The signal transmitting unit includes at least one signal transmitting cable between the surrounding electrode layer and the insulating layer and electrically connected to the surrounding electrode layer.

More precisely, the transparent substrate is one of a glass substrate and a plastic substrate, the plastic substrate is one of a polymethylmethacrylate (PMMA), a poly vinyl chloride (PVC), a polyethylene terephthalate (PET), a cyclic olefin copolymer (COC), a poly carbonate (PC), a polyethylene (PE), a poly propylene (PP), a poly styrene (PS) and a polyimide (PI) substrates. The transparent conductive layer is one of an indium tin oxide conductive layer, a carbon nanotube conductive layer, a polymer conductive layer, a grapheme conductive layer and a nano silver conductive layer, and the transparent substrate has a thickness substantially between 0.7 mm and 1.5 mm.

More precisely, the transparent conductive layer is a composite conductive layer including a conductive polymer material and one of a grapheme material and a carbon nanotube material.

More precisely, the surrounding electrode layer includes a base layer, a plurality of first conductive sections disposed on the base layer and arranged to form a surrounding shape, a plurality of second conductive sections disposed on the base layer to surround around the first conductive sections, a plurality of third conductive sections disposed on the base layer to surround around the first conductive sections, a plurality of fourth conductive sections disposed on the base layer to surround around the second conductive sections and the third conductive sections, and a plurality of fifth conductive sections disposed on the base layer to surround around the fourth conductive sections, and each second conductive section has a first conductive portion disposed between the two corresponding third conductive sections and a second conductive portion extended inwardly from the first conductive portion and disposed between the two corresponding first conductive sections.

More precisely, the transparent substrate has an outer surrounding surface, the transparent conductive layer has an outer surrounding surface, the insulating layer has an outer surrounding surface, the transparent substrate has a bottom surrounding area formed on the bottom surface thereof to adjacent to the outer surrounding surface of the transparent substrate and corresponds to the surrounding opaque layer, the transparent conductive layer has a top surrounding area formed on the top surface thereof to adjacent to the outer surrounding surface of the transparent conductive layer and corresponds to the surrounding opaque layer, and the surrounding opaque layer is formed between the bottom surrounding area of the transparent substrate and the top surrounding area of the transparent conductive layer, wherein the transparent conductive layer has a bottom surrounding area formed on the bottom surface thereof to adjacent to the outer surrounding surface of the transparent conductive layer and corresponds to the surrounding electrode layer, the insulating layer has a top surrounding area formed on the top surface thereof to adjacent to the outer surrounding surface of the insulating layer and corresponds to the surrounding electrode layer, and the surrounding electrode layer is formed between the bottom surrounding area of the transparent conductive layer and the top surrounding area of the insulating layer.

More precisely, the one-piece lamellar projective capacitive touch panel structure further comprises an auxiliary unit including at least two auxiliary coating layers respectively formed on the top surface of the transparent substrate and the bottom surface of the insulating layer, wherein each auxiliary coating layer is one of an optical film and an explosion-proof film.

More precisely, the one-piece lamellar projective capacitive touch panel structure further comprises an auxiliary unit including at least two auxiliary coating layers respectively formed on the top surface of the transparent substrate and the bottom surface of the insulating layer, wherein each auxiliary coating layer includes an optical film and an explosion-proof film stacked onto each other.

Another one of the embodiments of the instant disclosure provides a method of manufacturing a one-piece lamellar projective capacitive touch panel structure, comprising: providing a transparent substrate; surroundingly forming a surrounding opaque layer on the bottom surface of the transparent substrate; forming a transparent conductive layer on the bottom surface of the transparent substrate to cover the surrounding opaque layer; surroundingly forming a surrounding electrode layer on the bottom surface of the transparent conductive layer, wherein two opposite sides of the surrounding electrode layer is measured to obtain a terminal resistance substantially between 2000Ω and 2500Ω; forming an insulating layer on the bottom surface of the transparent conductive layer to cover the surrounding electrode layer; and then placing at least one signal transmitting cable between the surrounding electrode layer and the insulating layer, wherein the at least one signal transmitting cable is electrically connected to the surrounding electrode layer.

More precisely, the step of surroundingly forming the surrounding opaque layer on the bottom surface of the transparent substrate further comprises forming an opaque material layer on the bottom surface of the transparent substrate and removing a center region of the opaque material layer to form the surrounding opaque layer, wherein the step of surroundingly forming the surrounding electrode layer on the bottom surface of the transparent conductive layer further comprise forming an electrode material layer on the bottom surface of the transparent conductive layer and removing a center region of the electrode material layer to form the surrounding electrode layer.

More precisely, the transparent substrate is one of a glass substrate and a plastic substrate, the plastic substrate is one of a polymethylmethacrylate, a poly vinyl chloride, a polyethylene terephthalate, a cyclic olefin copolymer, a poly carbonate, a polyethylene, a poly propylene, a poly styrene and a polyimide substrates.

More precisely, the transparent conductive layer is one of an indium tin oxide conductive layer, a carbon nanotube conductive layer, a polymer conductive layer, a grapheme conductive layer and a nano silver conductive layer. The transparent conductive layer is a composite conductive layer including a conductive polymer material and one of a grapheme material and a carbon nanotube material.

More precisely, the surrounding electrode layer includes a base layer, a plurality of first conductive sections disposed on the base layer and arranged to form a surrounding shape, a plurality of second conductive sections disposed on the base layer to surround around the first conductive sections, a plurality of third conductive sections disposed on the base layer to surround around the first conductive sections, a plurality of fourth conductive sections disposed on the base layer to surround around the second conductive sections and the third conductive sections, and a plurality of fifth conductive sections disposed on the base layer to surround around the fourth conductive sections, and each second conductive section has a first conductive portion disposed between the two corresponding third conductive sections and a second conductive portion extended inwardly from the first conductive portion and disposed between the two corresponding first conductive sections.

More precisely, the method of manufacturing a one-piece lamellar projective capacitive touch panel structure further comprises: respectively forming at least two auxiliary coating layers on the top surface of the transparent substrate and the bottom surface of the insulating layer, wherein each auxiliary coating layer is one of an optical film and an explosion-proof film.

More precisely, the method of manufacturing a one-piece lamellar projective capacitive touch panel structure further comprises: respectively forming at least two auxiliary coating layers on the top surface of the transparent substrate and the bottom surface of the insulating layer, wherein each auxiliary coating layer includes an optical film and an explosion-proof film stacked onto each other.

Therefore, the transparent substrate is placed on the topmost side of the one-piece lamellar projective capacitive touch panel structure to form a topmost layer for user to touch it, thus the durability of the instant disclosure can be increased.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1 shows a perspective, exploded, schematic view of the one-piece lamellar projective capacitive touch panel structure according to the first embodiment of the instant disclosure;

FIG. 2 shows a perspective, assembled, schematic view of the one-piece lamellar projective capacitive touch panel structure according to the first embodiment of the instant disclosure;

FIG. 3 shows a lateral, cross-sectional, schematic view of the one-piece lamellar projective capacitive touch panel structure according to the first embodiment of the instant disclosure;

FIG. 4 shows a partial, top, schematic view of the surrounding electrode layer of the one-piece lamellar projective capacitive touch panel structure according to the first embodiment of the instant disclosure;

FIG. 5 shows a flowchart of the method of manufacturing the one-piece lamellar projective capacitive touch panel structure according to the first embodiment of the instant disclosure;

FIG. 6A shows a cross-sectional, schematic view of the step S100 and the step S102 of the method of manufacturing the one-piece lamellar projective capacitive touch panel structure according to the first embodiment of the instant disclosure;

FIG. 6B shows a cross-sectional, schematic view of the step S104 of the method of manufacturing the one-piece lamellar projective capacitive touch panel structure according to the first embodiment of the instant disclosure;

FIG. 6C shows a cross-sectional, schematic view of the step S106 of the method of manufacturing the one-piece lamellar projective capacitive touch panel structure according to the first embodiment of the instant disclosure;

FIG. 6D shows a cross-sectional, schematic view of the step S108 of the method of manufacturing the one-piece lamellar projective capacitive touch panel structure according to the first embodiment of the instant disclosure;

FIG. 6E shows a cross-sectional, schematic view of the step S110 of the method of manufacturing the one-piece lamellar projective capacitive touch panel structure according to the first embodiment of the instant disclosure;

FIG. 6F shows a cross-sectional, schematic view of the step S112 of the method of manufacturing the one-piece lamellar projective capacitive touch panel structure according to the first embodiment of the instant disclosure;

FIG. 7 shows a lateral, cross-sectional, schematic view of the one-piece lamellar projective capacitive touch panel structure according to the second embodiment of the instant disclosure; and

FIG. 8 shows a lateral, cross-sectional, schematic view of the one-piece lamellar projective capacitive touch panel structure according to the third embodiment of the instant disclosure.

### DETAILED DESCRIPTION OF THE PREFERRED EMBODIMENTS

### First Embodiment

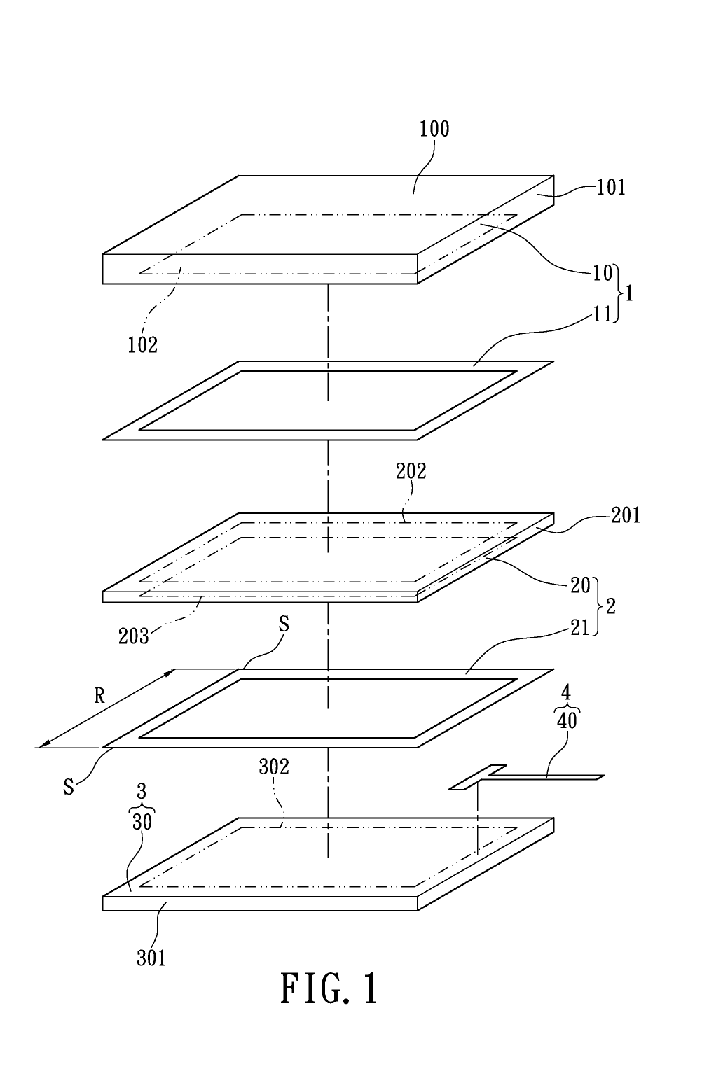

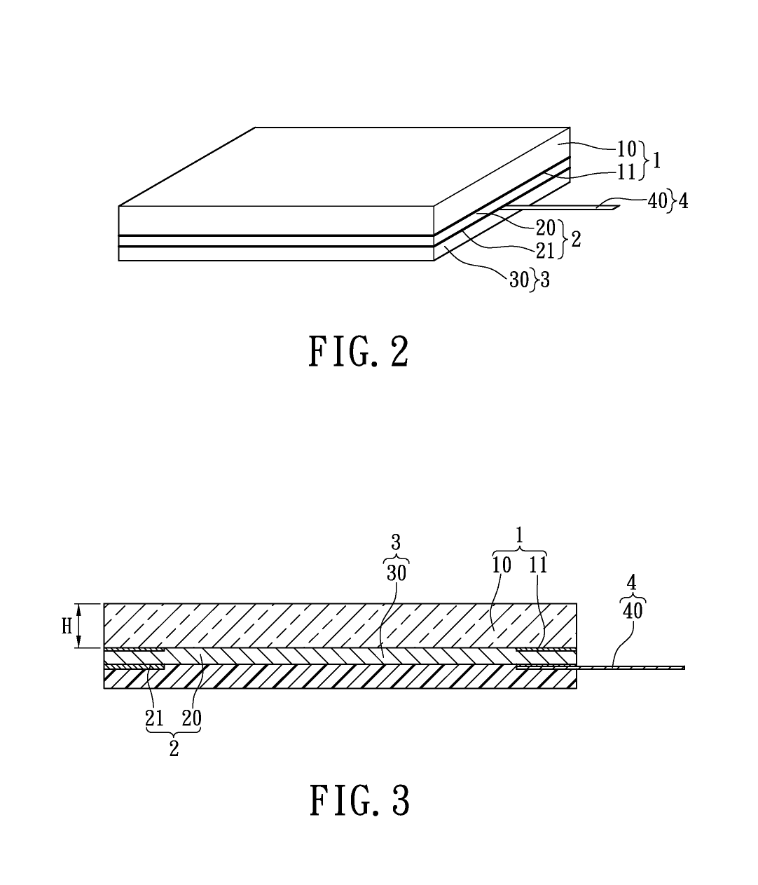

Referring to FIG. 1 to FIG. 4, where the first embodiment of the instant disclosure provides a one-piece (single) lamellar projective capacitive touch panel structure, comprising: a substrate unit 1, a conductive unit 2, an insulating unit 3 and a signal transmitting unit 4.

Referring to FIG. 1 to FIG. 3, the substrate unit 1 includes a transparent substrate 10 and a surrounding opaque layer 11 (such as a black frame) surroundingly formed on the bottom surface of the transparent substrate 10. For example, the transparent substrate 10 has a thickness H substantially between 0.7 mm and 1.5 mm. The transparent substrate 10 may be a glass substrate or a plastic substrate. When the transparent substrate 10 is a glass substrate, the transparent substrate 10 has a touch surface 100 formed on the top side thereof for user to touch it. In addition, when the transparent substrate 10 is a plastic substrate, the plastic substrate has a hard coating layer (not shown) formed on the top surface thereof, and the touch surface 100 is formed on the top side of the hard coating layer (not shown), where the plastic substrate may be a polymethylmethacrylate (PMMA), a poly vinyl chloride (PVC), a polyethylene terephthalate (PET), a cyclic olefin copolymer (COC), a poly carbonate (PC), a polyethylene (PE), a poly propylene (PP), a poly styrene (PS) or a polyimide (PI) substrates, and the hard coating layer (not shown) may be a silicon dioxide layer. However, the above-mentioned design for the transparent substrate 10 of the first embodiment is merely an example and is not meant to limit the instant disclosure.

Moreover, referring to FIG. 1 to FIG. 3, the conductive unit 2 includes a transparent conductive layer 20 formed on the bottom surface of the transparent substrate 10 to cover the surrounding opaque layer 11 and a surrounding electrode layer 21 surroundingly formed on the bottom surface of the transparent conductive layer 20, where two opposite sides S of the surrounding electrode layer 21 is measured to obtain a terminal resistance R substantially between 2000Ω and 2500Ω, the perfect terminal resistance R is over 2300Ω. In addition, the surrounding opaque layer 11 can be disposed above the surrounding electrode layer 21 and the surrounding opaque layer 11 has an area larger than that of the surrounding electrode layer 21, thus the surrounding electrode layer 21 can be hidden completely by the surrounding opaque layer 11 without using any extra mechanism design. For example, the transparent conductive layer 20 may be an indium tin oxide (ITO) conductive layer, a carbon nanotube (CNT) conductive layer, a polymer conductive layer, a grapheme conductive layer or a nano silver conductive layer. In addition, the transparent conductive layer 20 may be a composite conductive layer composed of more than two conductive materials according to different requirements, for example, the transparent conductive layer 20 may be a composite conductive layer including a conductive polymer material and one of a grapheme material and a carbon nanotube material. Moreover, the surrounding electrode layer 21 can be made of conductive material having a good electrical conductivity such as silver paste or metal filaments. However, the above-mentioned design for the transparent conductive layer 20 and the surrounding electrode layer 21 of the first embodiment is merely an example and is not meant to limit the instant disclosure.

Furthermore, the insulating unit 3 includes an insulating layer 30 formed on the bottom surface of the transparent conductive layer 20 to cover the surrounding electrode layer 21. For example, the insulating layer 30 may be a protection layer, a hard coating, a PET (Polyethylene Terephthalate) layer or any type of insulating film. However, the above-mentioned design for the insulating layer 30 of the first embodiment is merely an example and is not meant to limit the instant disclosure.

In addition, the signal transmitting unit 4 includes at least one signal transmitting cable 40 between the surrounding electrode layer 21 and the insulating layer 30 and electrically connected to the surrounding electrode layer 21. For example, the signal transmitting cable 40 may be a flexible cable or any transmission cable for transmitting signals. However, the above-mentioned design for the signal transmitting cable 40 of the first embodiment is merely an example and is not meant to limit the instant disclosure.

More precisely, referring to FIG. 1 to FIG. 3, the transparent substrate 10 has an outer surrounding surface 101, the transparent conductive layer 20 has an outer surrounding surface 201, and the insulating layer 30 has an outer surrounding surface 301, where the transparent substrate 10 has a bottom surrounding area 102 formed on the bottom surface of the transparent substrate 10 to adjacent to the outer surrounding surface 101 of the transparent substrate 10 and corresponds to the surrounding opaque layer 11, the transparent conductive layer 20 has a top surrounding area 202 formed on the top surface thereof to adjacent to the outer surrounding surface 201 of the transparent conductive layer 20 and corresponds to the surrounding opaque layer 11, and the surrounding opaque layer 11 is formed between the bottom surrounding area 102 of the transparent substrate 10 and the top surrounding area 202 of the transparent conductive layer 20. In addition, the transparent conductive layer 20 has a bottom surrounding area 203 formed on the bottom surface of the transparent conductive layer 20 to adjacent to the outer surrounding surface 201 of the transparent conductive layer 20 and corresponds to the surrounding electrode layer 21, the insulating layer 30 has a top surrounding area 302 formed on the top surface of the insulating layer 30 to adjacent to the outer surrounding surface 301 of the insulating layer 30 and corresponds to the surrounding electrode layer 21, and the surrounding electrode layer 21 is formed between the bottom surrounding area 203 of the transparent conductive layer 20 and the top surrounding area 302 of the insulating layer 30. However, the above-mentioned position design for the surrounding opaque layer 11 and the surrounding electrode layer 21 of the first embodiment is merely an example and is not meant to limit the instant disclosure.

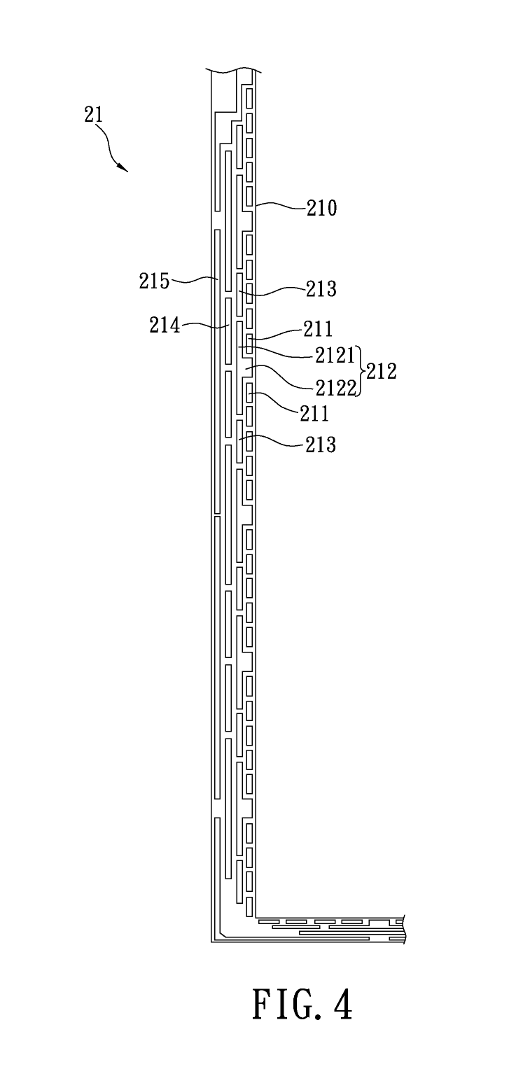

More precisely, referring to FIG. 1 and FIG. 4, where FIG. 4 only shows a half of the surrounding electrode layer 21 including at least six positions for electrically connecting resistances in series. The surrounding electrode layer 21 includes a base layer 210, a plurality of first conductive sections 211 disposed on the base layer 210 and surroundingly arranged to form a surrounding shape, a plurality of second conductive sections 212 disposed on the base layer 210 to surround around the first conductive sections 211, a plurality of third conductive sections 213 disposed on the base layer 210 to surround around the first conductive sections 211, a plurality of fourth conductive sections 214 disposed on the base layer 210 to surround around the second conductive sections 212 and the third conductive sections 213, and a plurality of fifth conductive sections 215 disposed on the base layer 210 to surround around the fourth conductive sections 214. Each second conductive section 212 has a first conductive portion 2121 disposed between the two corresponding third conductive sections 213 and a second conductive portion 2122 extended inwardly from the first conductive portion 2121 and disposed between the two corresponding first conductive sections 211.

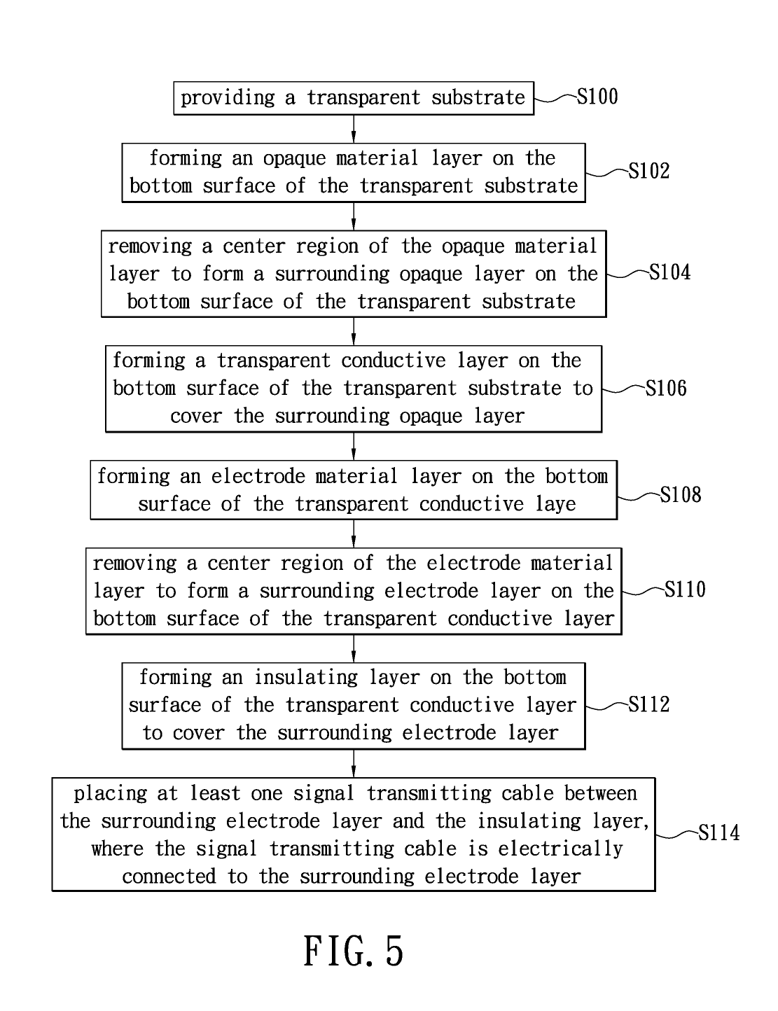

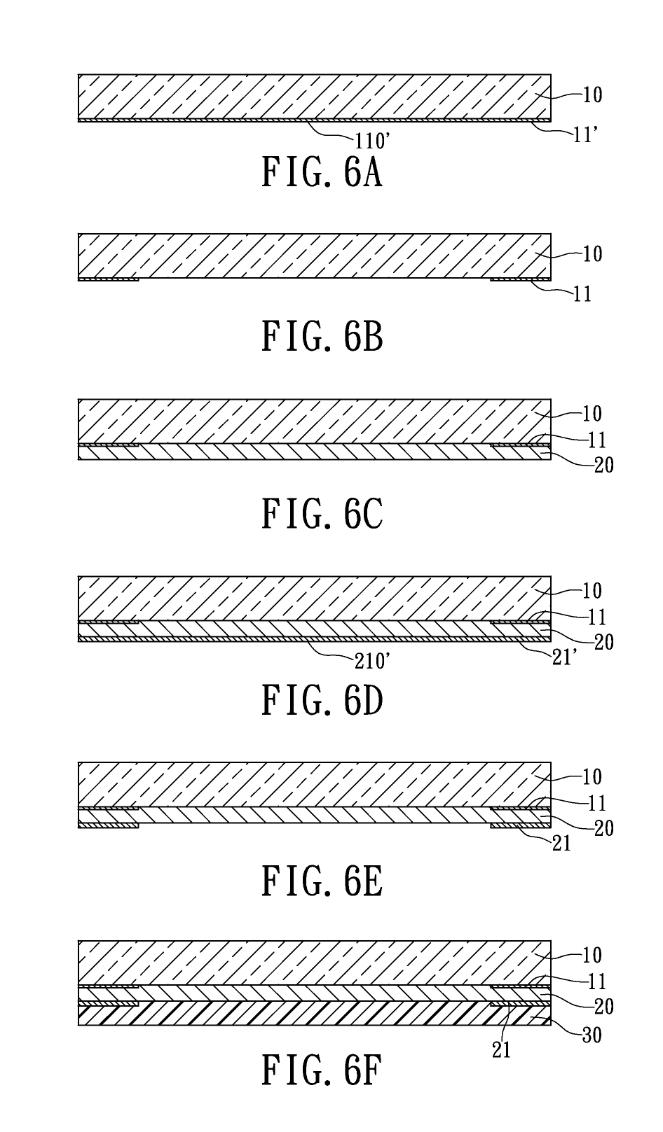

Referring to FIG. 5, and FIG. 6A to FIG. 6F, the first embodiment of the instant disclosure provides a method of manufacturing a one-piece lamellar projective capacitive touch panel structure is shown as follows:

First, referring to FIG. 5 and FIG. 6A, the method comprises: providing a transparent substrate 10 (as shown in the step of S100), and then forming an opaque material layer 11′ on the bottom surface of the transparent substrate 10 (as shown in the step of S102). For example, the opaque material layer 11′ can be formed on the bottom surface of the transparent substrate 10 by printing, coating, sputtering, vapor deposition or any other forming method. However, the above-mentioned method of forming the opaque material layer 11′ of the first embodiment is merely an example and is not meant to limit the instant disclosure.

Next, referring to FIG. 5, FIG. 6A and FIG. 6B, the method further comprises: removing a center region 110′ of the opaque material layer 11′ to form a surrounding opaque layer 11 on the bottom surface of the transparent substrate 10 (as shown in the step of S104). For example, the center region 110′ of the opaque material layer 11′ can be removed or penetrated by etching or any removing method. However, the above-mentioned method of removing the center region 110′ of the opaque material layer 11′ of the first embodiment is merely an example and is not meant to limit the instant disclosure.

Then, referring to FIG. 5 and FIG. 6C, the method further comprises: forming a transparent conductive layer 20 on the bottom surface of the transparent substrate 10 to cover the surrounding opaque layer 11 (as shown in the step of S106). For example, the transparent conductive layer 20 can be formed on the bottom surface of the transparent substrate 10 by printing, coating, sputtering, vapor deposition or any other forming method. However, the above-mentioned method of forming the transparent conductive layer 20 of the first embodiment is merely an example and is not meant to limit the instant disclosure.

Afterward, referring to FIG. 5 and FIG. 6D, the method further comprises: forming an electrode material layer 21′ on the bottom surface of the transparent conductive layer 20 (as shown in the step of S108). For example, the electrode material layer 21′ can be formed on the bottom surface of the transparent conductive layer 20 by printing, coating, sputtering, vapor deposition or any other forming method. However, the above-mentioned method of forming the electrode material layer 21′ of the first embodiment is merely an example and is not meant to limit the instant disclosure.

Next, referring to FIG. 5, FIG. 6D and FIG. 6E, the method further comprises: removing a center region 210′ of the electrode material layer 21′ to form a surrounding electrode layer 21 on the bottom surface of the transparent conductive layer 20 (as shown in the step of S110). For example, the center region 210′ of the electrode material layer 21′ can be removed or penetrated by etching or any removing method. However, the above-mentioned method of removing the center region 210′ of the electrode material layer 21′ of the first embodiment is merely an example and is not meant to limit the instant disclosure. Furthermore, two opposite sides S of the surrounding electrode layer 21 is measured to obtain a terminal resistance R substantially between 2000Ω and 2500Ω as shown in FIG. 1.

Then, referring to FIG. 5 and FIG. 6, the method further comprises: forming an insulating layer 30 on the bottom surface of the transparent conductive layer 20 to cover the surrounding electrode layer 21 (as shown in the step of S112). For example, insulating layer 30 can be formed on the bottom surface of the transparent conductive layer 20 by printing, coating, sputtering, vapor deposition or any other forming method. However, the above-mentioned method of forming the insulating layer 30 of the first embodiment is merely an example and is not meant to limit the instant disclosure.

Finally, referring to FIG. 5 and FIG. 3, the method further comprises: placing at least one signal transmitting cable 40 between the surrounding electrode layer 21 and the insulating layer 30, where the signal transmitting cable 40 is electrically connected to the surrounding electrode layer 21 (as shown in the step of S114). For example, the instant disclosure can design an insert hole (not shown) between the transparent conductive layer 20 and the insulating layer 30 in advance, the signal transmitting cable 40 can be inserted into the insert hole after finishing the step of S114, thus the signal transmitting cable 40 can be placed between the surrounding electrode layer 21 and the insulating layer 30 and electrically connected to the surrounding electrode layer 21.

### Second Embodiment

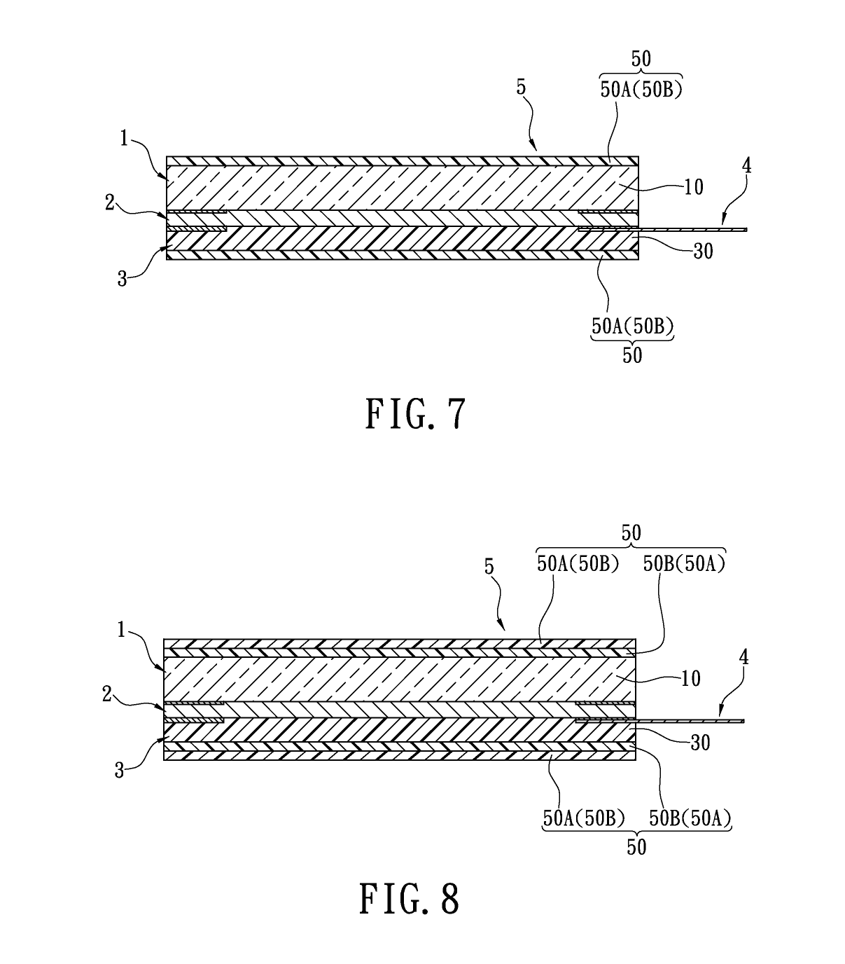

Referring to FIG. 7, where the second embodiment of the instant disclosure provides a one-piece lamellar projective capacitive touch panel structure, comprising: a substrate unit 1, a conductive unit 2, an insulating unit 3 and a signal transmitting unit 4. Comparing FIG. 7 with FIG. 3, the difference between the second embodiment and the first embodiment is as follows: in the second embodiment, the one-piece lamellar projective capacitive touch panel structure further comprises an auxiliary unit 5 that includes at least two auxiliary coating layers 50 respectively formed on the top surface of the transparent substrate 10 and the bottom surface of the insulating layer 30, where each auxiliary coating layer 50 may be an optical film 50A for increasing the transmittance or an explosion-proof film 50B for increasing the security, and the optical film 50A and the explosion-proof film 50B can be made of PET. More precisely, the method of the instant disclosure can further comprising: respectively forming at least two auxiliary coating layers 50 on the top surface of the transparent substrate 10 and the bottom surface of the insulating layer 30. However, the above-mentioned design of the two auxiliary coating layers 50 of the second embodiment is merely an example and is not meant to limit the instant disclosure.

### Third Embodiment

Referring to FIG. 8, where the third embodiment of the instant disclosure provides a one-piece lamellar projective capacitive touch panel structure, comprising: a substrate unit 1, a conductive unit 2, an insulating unit 3 and a signal transmitting unit 4. Comparing FIG. 8 with FIG. 3, the difference between the third embodiment and the first embodiment is as follows: in the third embodiment, the one-piece lamellar projective capacitive touch panel structure further comprises an auxiliary unit 5 that includes at least two auxiliary coating layers 50 respectively formed on the top surface of the transparent substrate 10 and the bottom surface of the insulating layer 30, where each auxiliary coating layer 50 includes an optical film 50A for increasing the transmittance and an explosion-proof film 50B for increasing the security, and the optical film 50A and the explosion-proof film 50B can be stacked onto each other. More precisely, the method of the instant disclosure can further comprising: respectively forming at least two auxiliary coating layers 50 on the top surface of the transparent substrate 10 and the bottom surface of the insulating layer 30. However, the above-mentioned design of the two auxiliary coating layers 50 of the third embodiment is merely an example and is not meant to limit the instant disclosure.

The above-mentioned descriptions merely represent the preferred embodiments of the instant disclosure, without any intention or ability to limit the scope of the instant disclosure which is fully described only within the following claims Various equivalent changes, alterations or modifications based on the claims of instant disclosure are all, consequently, viewed as being embraced by the scope of the instant disclosure.

What is claimed is:

1. A one-piece lamellar projective capacitive touch panel structure, comprising:
a substrate unit including a transparent substrate and a surrounding opaque layer surroundingly formed on the bottom surface of the transparent substrate;
a conductive unit including a transparent conductive layer formed on the bottom surface of the transparent substrate to cover the surrounding opaque layer and a surrounding electrode layer surroundingly formed on the bottom surface of the transparent conductive layer, wherein two opposite sides of the surrounding electrode layer is measured to obtain a terminal resistance substantially between 2000Ω and 2500Ω;
an insulating unit including an insulating layer formed on the bottom surface of the transparent conductive layer to cover the surrounding electrode layer; and
a signal transmitting unit including at least one signal transmitting cable between the surrounding electrode layer and the insulating layer and electrically connected to the surrounding electrode layer.

2. The one-piece lamellar projective capacitive touch panel structure of claim 1, wherein the transparent substrate is one of a glass substrate and a plastic substrate, the plastic substrate has a hard coating layer formed on the top surface thereof, the plastic substrate is one of a polymethylmethacrylate (PMMA), a poly vinyl chloride (PVC), a polyethylene terephthalate (PET), a cyclic olefin copolymer (COC), a poly carbonate (PC), a polyethylene (PE), a poly propylene (PP), a poly styrene (PS) and a polyimide (PI) substrates, and the hard coating layer is a silicon dioxide layer.

3. The one-piece lamellar projective capacitive touch panel structure of claim 1, wherein the transparent conductive layer is one of an indium tin oxide conductive layer, a carbon nanotube conductive layer, a polymer conductive layer, a grapheme conductive layer and a nano silver conductive layer, and the transparent substrate has a thickness substantially between 0.7 mm and 1.5 mm.

4. The one-piece lamellar projective capacitive touch panel structure of claim 1, wherein the transparent conductive layer is a composite conductive layer including a conductive polymer material and one of a grapheme material and a carbon nanotube material.

5. The one-piece lamellar projective capacitive touch panel structure of claim 1, wherein the surrounding electrode layer includes a base layer, a plurality of first conductive sections disposed on the base layer and arranged to form a surrounding shape, a plurality of second conductive sections disposed on the base layer to surround around the first conductive sections, a plurality of third conductive sections disposed on the base layer to surround around the first conductive sections, a plurality of fourth conductive sections disposed on the base layer to surround around the second conductive sections and the third conductive sections, and a plurality of fifth conductive sections disposed on the base layer to surround around the fourth conductive sections, and each second conductive section has a first conductive portion disposed between the two corresponding third conductive sections and a second conductive portion extended inwardly from the first conductive portion and disposed between the two corresponding first conductive sections.

6. The one-piece lamellar projective capacitive touch panel structure of claim 1, wherein the transparent substrate has an outer surrounding surface, the transparent conductive layer has an outer surrounding surface, the insulating layer has an outer surrounding surface, the transparent substrate has a bottom surrounding area formed on the bottom surface thereof to adjacent to the outer surrounding surface of the transparent substrate and corresponds to the surrounding opaque layer, the transparent conductive layer has a top surrounding area formed on the top surface thereof to adjacent to the outer surrounding surface of the transparent conductive layer and corresponds to the surrounding opaque layer, and the surrounding opaque layer is formed between the bottom surrounding area of the transparent substrate and the top surrounding area of the transparent conductive layer, wherein the transparent conductive layer has a bottom surrounding area formed on the bottom surface thereof to adjacent to the outer surrounding surface of the transparent conductive layer and corresponds to the surrounding electrode layer, the insulating layer has a top surrounding area formed on the top surface thereof to adjacent to the outer surrounding surface of the insulating layer and corresponds to the surrounding electrode layer, and the surrounding electrode layer is formed between the bottom surrounding area of the transparent conductive layer and the top surrounding area of the insulating layer.

7. The one-piece lamellar projective capacitive touch panel structure of claim 1, further comprising an auxiliary unit including at least two auxiliary coating layers respectively formed on the top surface of the transparent substrate and the bottom surface of the insulating layer, wherein each auxiliary coating layer is one of an optical film and an explosion-proof film.

8. The one-piece lamellar projective capacitive touch panel structure of claim 1, further comprising an auxiliary unit including at least two auxiliary coating layers respectively formed on the top surface of the transparent substrate and the bottom surface of the insulating layer, wherein each auxiliary coating layer includes an optical film and an explosion-proof film stacked onto each other.

9. A method of manufacturing a one-piece lamellar projective capacitive touch panel structure, comprising:
providing a transparent substrate;
surroundingly forming a surrounding opaque layer on the bottom surface of the transparent substrate;
forming a transparent conductive layer on the bottom surface of the transparent substrate to cover the surrounding opaque layer;
surroundingly forming a surrounding electrode layer on the bottom surface of the transparent conductive layer, wherein two opposite sides of the surrounding electrode layer is measured to obtain a terminal resistance substantially between 2000Ω and 2500Ω;
forming an insulating layer on the bottom surface of the transparent conductive layer to cover the surrounding electrode layer; and
placing at least one signal transmitting cable between the surrounding electrode layer and the insulating layer, wherein the at least one signal transmitting cable is electrically connected to the surrounding electrode layer.

10. The method of claim 9, wherein the step of surroundingly forming the surrounding opaque layer on the bottom surface of the transparent substrate further comprises forming an opaque material layer on the bottom surface of the transparent substrate and removing a center region of the opaque material layer to form the surrounding opaque layer, wherein the step of surroundingly forming the surrounding electrode layer on the bottom surface of the transparent conductive layer further comprise forming an electrode material layer on the bottom surface of the transparent conductive layer and removing a center region of the electrode material layer to form the surrounding electrode layer.

11. The method of claim 9, wherein the transparent substrate is one of a glass substrate and a plastic substrate, the plastic substrate has a hard coating layer formed on the top surface thereof, the plastic substrate is one of a polymethylmethacrylate (PMMA), a poly vinyl chloride (PVC), a polyethylene terephthalate (PET), a cyclic olefin copolymer (COC), a poly carbonate (PC), a polyethylene (PE), a poly propylene (PP), a poly styrene (PS) and a polyimide (PI) substrates, and the hard coating layer is a silicon dioxide layer.

12. The method of claim 9, wherein the transparent conductive layer is one of an indium tin oxide conductive layer, a carbon nanotube conductive layer, a polymer conductive layer, a grapheme conductive layer and a nano silver conductive layer, and the transparent substrate has a thickness substantially between 0.7 mm and 1.5 mm.

13. The method of claim 9, wherein the transparent conductive layer is a composite conductive layer including a conductive polymer material and one of a grapheme material and a carbon nanotube material.

14. The method of claim 9, wherein the surrounding electrode layer includes a base layer, a plurality of first conductive sections disposed on the base layer and arranged to form a surrounding shape, a plurality of second conductive sections disposed on the base layer to surround around the first conductive sections, a plurality of third conductive sections disposed on the base layer to surround around the first conductive sections, a plurality of fourth conductive sections disposed on the base layer to surround around the second conductive sections and the third conductive sections, and a plurality of fifth conductive sections disposed on the base layer to surround around the fourth conductive sections, and each second conductive section has a first conductive portion disposed between the two corresponding third conductive sections and a second conductive portion extended inwardly from the first conductive portion and disposed between the two corresponding first conductive sections.

15. The method of claim 9, wherein the transparent substrate has an outer surrounding surface, the transparent conductive layer has an outer surrounding surface, the insulating layer has an outer surrounding surface, the transparent substrate has a bottom surrounding area formed on the bottom surface thereof to adjacent to the outer surrounding surface of the transparent substrate and corresponds to the surrounding opaque layer, the transparent conductive layer has a top surrounding area formed on the top surface thereof to adjacent to the outer surrounding surface of the transparent conductive layer and corresponds to the surrounding opaque layer, and the surrounding opaque layer is formed between the bottom surrounding area of the transparent substrate and the top surrounding area of the transparent conductive layer, wherein the transparent conductive layer has a bottom surrounding area formed on the bottom surface thereof to adjacent to the outer surrounding surface of the transparent conductive layer and corresponds to the surrounding electrode layer, the insulating layer has a top surrounding area formed on the top surface thereof to adjacent to the outer surrounding surface of the insulating layer and corresponds to the surrounding electrode layer, and the surrounding electrode layer is formed between the bottom surrounding area of the transparent conductive layer and the top surrounding area of the insulating layer.

16. The method of claim 9, further comprising: respectively forming at least two auxiliary coating layers on the top surface of the transparent substrate and the bottom surface of the insulating layer, wherein each auxiliary coating layer is one of an optical film and an explosion-proof film.

17. The method of claim 9, further comprising: respectively forming at least two auxiliary coating layers on the top surface of the transparent substrate and the bottom surface of the insulating layer, wherein each auxiliary coating layer includes an optical film and an explosion-proof film stacked onto each other.
